(19) United States
(12) Patent Application Publication
(10) Pub. No.: US 2023/0420705 A1
(43) Pub. Date: Dec. 28, 2023

(54) SYSTEM AND METHOD OF INSPECTING AN AIR COMPRESSOR FOR A FUEL CELL

(71) Applicants: HYUNDAI MOTOR COMPANY, Seoul (KR); KIA CORPORATION, Seoul (KR)

(72) Inventors: Joo Yeon Kim, Seoul (KR); Min Su Kang, Paju-si (KR); Tae Young Kim, Suwon-si (KR); Sung Do Kim, Seoul (KR); Chang Seok You, Hwaseong-si (KR)

(73) Assignees: HYUNDAI MOTOR COMPANY, Seoul (KR); KIA CORPORATION, Seoul (KR)

(21) Appl. No.: 17/943,991

(22) Filed: Sep. 13, 2022

(30) Foreign Application Priority Data
May 19, 2022 (KR) 10-2022-0061528

(51) Int. Cl. H01M 8/04111; H01M 8/04746

(52) U.S. Cl. CPC H01M 8/04111; H01M 8/04776; H01M 8/04753

(57) ABSTRACT

A system and a method of inspecting an air compressor for a fuel cell are proposed. The inspection system includes a fuel cell; an air compressor provided on an inlet side of a cathode of the fuel cell and provided with a motor; and a controller configured to calculate an estimated consumption current of the air-compressor motor through a relationship between an applied voltage and a rotation speed of the air-compressor motor and configured to compare the calculated estimated consumption current with a measured actual consumption current to determine whether a permanent magnet of the air-compressor motor is demagnetized.

### CROSS REFERENCE TO RELATED APPLICATION

The present application claims priority to Korean Patent Application No. 10-2022-0061528, filed May 19, 2022, the entire contents of which are incorporated herein for all purposes by this reference.

### BACKGROUND OF THE DISCLOSURE

### Field of the Disclosure

The present disclosure relates to a system and a method of inspecting an air compressor for a fuel cell. In the system and the method, an estimated consumption current of an air-compressor motor is calculated through a relationship between an applied voltage and a rotation speed of the air-compressor motor. The calculated estimated consumption current is compared with measured actual consumption current. Thus, accuracy is enhanced when it is determined that a permanent magnet of the air-compressor motor is demagnetized.

### Description of the Related Art

An air compressor provided in a fuel cell vehicle and provided to supply air to a fuel cell drives a motor to generate an air flow. A permanent magnet, which is one of the main components constituting the motor of the air compressor, has irreversible demagnetization, in which a magnetic flux decreases over time. Due to the demagnetization of the permanent magnet, a magnetic flux lower than an initial design value is formed. Thus, the maximum drivable speed of the air-compressor motor is reduced.

In particular, the air-compressor motor for the fuel cell vehicle is a motor that is reduced in size in spite of high speed and high power and has a large effect on power when the permanent magnet is demagnetized. Further, in a state where the motor drivable speed is reduced due to the demagnetization of the permanent magnet, the supply of air into the fuel cell becomes insufficient compared to the initial design value. Thus, when high power is required while the fuel cell vehicle is driving, the cell voltage in the fuel cell drops momentarily. When the cell voltage drops momentarily, a current limiting function is performed to protect the fuel cell. However, there is a problem in that the power of the vehicle fluctuates and acceleration is restricted. Furthermore, when the irreversible demagnetization of the air-compressor motor is maintained, the speed-up command of the air compressor is maintained to match speed, flow rate, and power. Thus, this causes an increase in temperature of the motor and leads to the determination of a failure of a fuel cell system.

In order to solve the problem, it is determined whether the demagnetization occurs by comparing a back electromotive force (EMF) constant calculated using a motor three-phase voltage equation and a back EMF constant in a state where demagnetization does not occur. However, due to the measurement error of factors used in the three-phase voltage equation and the occurrence of deviation in design, an error occurs when calculating the back EMF constant using the three-phase voltage equation, so accuracy may be deteriorated in diagnosing the demagnetization of the motor. In addition, when it is not a maximum power section, the generated back EMF is small. Thus, it is difficult to clearly determine that it is due to the demagnetization of the motor when comparing the design value of the back EMF constant and the calculated value. Furthermore, when the motor demagnetization is diagnosed with the calculated back EMF constant through the three-phase voltage equation using only variables in the air compressor, this does not take into account the influence of change in the fuel cell system.

The foregoing is intended merely to aid in understanding the background of the present disclosure. The foregoing is not intended to mean that the present disclosure falls within the purview of the related art that is already known to those having ordinary skill in the art.

### SUMMARY

Accordingly, the present disclosure has been made keeping in mind the above problems occurring in the related art. An objective of the present disclosure is to provide a system and a method of inspecting an air compressor for a fuel cell. In the system and the method, the estimated consumption current of an air-compressor motor is calculated through a relationship between the applied voltage and rotation speed of the air-compressor motor. The calculated estimated consumption current is compared with measured actual consumption current. Thus, accuracy is enhanced when it is determined that a permanent magnet of the air-compressor motor is demagnetized.

In order to achieve the objective of the present disclosure, the present disclosure provides an inspection system of an air compressor for a fuel cell. The inspection system includes the fuel cell; an air compressor provided on an inlet side of a cathode of the fuel cell and provided with a motor; and a controller. The controller is configured to calculate an estimated consumption current of the motor of the air-compressor through a relationship between an applied voltage and a rotation speed of the motor of the air-compressor. The controller is also configured to compare the calculated estimated consumption current with a measured actual consumption current to determine whether a permanent magnet of the motor of the air-compressor is demagnetized.

The inspection system may further include an air control valve provided on an outlet side of the cathode of the fuel cell. The inspection system may further include a pressure sensor provided between the air compressor and the air control valve to measure pressure of air discharged from the air compressor. The inspection system may further include a flow-rate sensor provided between the air compressor and the air control valve to measure a flow rate of air discharged from the air compressor. The controller may estimate a relationship between a power and a rotation speed of the motor of the air-compressor through a relationship between the pressure and the flow rate measured through the pressure sensor and the flow-rate sensor in a state where an opening degree of the air control valve is fixed.

The controller may calculate a correction coefficient through the relationship between the power and the rotation speed of the motor of the air-compressor. The relationship between the power and the rotation speed of the motor of the air-compressor is estimated in a state where the opening degree of the air control valve is fixed. The controller may store the calculated correction coefficient to correspond to the opening degree of the air control valve.

The controller may include a data map outputting the correction coefficient corresponding to an input opening degree of the air control valve and may store the calculated correction coefficient in the data map.

The controller may check the opening degree of the air control valve when the estimated consumption current is calculated and may derive the correction coefficient corresponding to the checked opening degree of the air control valve. The controller may calculate the estimated consumption current by reflecting the derived correction coefficient in the relationship between the applied voltage and the rotation speed of the motor of the air-compressor.

The controller may calculate the estimated consumption current of the motor of the air-compressor in a state where the motor of the air-compressor enters a rotation-speed maintaining section. The controller may determine whether the permanent magnet of the motor of the air-compressor is demagnetized by comparing the calculated estimated consumption current with the measured actual consumption current.

The rotation-speed maintaining section of the motor of the air-compressor may be a section in which there is no change in an amount of current applied to the motor of the air-compressor.

The controller may measure current that is consumed by the motor of the air-compressor after the motor of the air-compressor enters the rotation-speed maintaining section. The controller may also calculate an average value of current consumed for each reference time. The controller may also use the calculated average value as the actual consumption current of the motor of the air-compressor.

The controller may designate a normal range of the calculated estimated consumption current when comparing the calculated estimated consumption current with the actual consumption current. The controller may also check whether the measured actual consumption current falls within the normal range of the estimated consumption current. The controller may also count a number of deviations when the actual consumption current deviates from the normal range of the estimated consumption current.

If the measured actual consumption current is within the normal range of the estimated consumption current, the controller may determine whether the rotation-speed maintaining section of the motor of the air-compressor is completed. The controller may also determine completion of the rotation-speed maintaining section as a normal state where the demagnetization of the permanent magnet of the motor of the air-compressor does not occur.

The controller may check whether the opening degree of the air control valve is maintained at the opening degree when entering the rotation-speed maintaining section of the motor of the air-compressor, if the rotation-speed maintaining section of the motor of the air-compressor is not completed. The controller may also measure the actual consumption current of the motor of the air-compressor again when the opening degree of the air control valve is maintained.

The controller may compare the counted number with a pre-stored reference number of determining the demagnetization of the permanent magnet of the motor of the air-compressor when the actual consumption current deviates from the normal range of the estimated consumption current. The controller may also determine that the demagnetization occurs in the permanent magnet of the motor of the air-compressor when the counted number is equal to or more than the reference number.

When the counted number is less than the reference number, the controller may check whether the opening degree of the air control valve is maintained at an opening degree when the motor of the air-compressor enters the rotation-speed maintaining section. When the opening degree of the air control valve is maintained, the controller may measure the actual consumption current of the motor of the air-compressor again.

In order to achieve the objective of the present disclosure, the present disclosure provides an inspection method of an air compressor for a fuel cell. The inspection method includes deriving, by a controller, an applied voltage and a rotation speed of an air-compressor motor. The inspection method also includes calculating, by the controller, estimated consumption current of the air-compressor motor through a relationship between the applied voltage and the rotation speed of the air-compressor motor. The inspection method also includes determining whether a permanent magnet of the air-compressor motor is demagnetized by comparing the estimated consumption current calculated by the controller with measured actual consumption current.

In the calculating of the estimated consumption current of the air-compressor motor, the estimated consumption current of the air-compressor motor may be calculated by reflecting a correction coefficient in the relationship between the applied voltage and the rotation speed of the air-compressor motor in the controller. The correction coefficient may be derived according to the opening degree of the air control valve. The correction coefficient may be calculated through a relationship between power and the rotation speed of the air-compressor motor to be stored together with the opening degree of the air control valve.

In the determining whether the permanent magnet of the air-compressor motor is demagnetized, the controller may designate a normal range of the calculated estimated consumption current, may check whether the measured actual consumption current falls with the normal range of the estimated consumption current, and may determine whether the permanent magnet of the air-compressor motor is demagnetized.

A system and method of inspecting an air compressor for a fuel cell according to the present disclosure are advantageous in that the estimated consumption current of an air-compressor motor is calculated through a relationship between the applied voltage and rotation speed of the air-compressor motor. It is thus determined that a permanent magnet of the air-compressor motor is demagnetized. Thus, the occurrence of determination errors due to errors of measurement elements and design deviations may be reduced and the accuracy may be enhanced.

Furthermore, when it is determined that a permanent magnet of an air-compressor motor is demagnetized, both internal and external elements of an air compressor are inspected. Thus, the accuracy of determining that the air-compressor motor is demagnetized may be enhanced.

### BRIEF DESCRIPTION OF THE DRAWINGS

The above and other objectives, features, and other advantages of the present disclosure should be more clearly understood from the following detailed description when taken in conjunction with the accompanying drawings, in which:

FIG. 1 is a diagram illustrating the configuration of an inspection system of an air compressor for a fuel cell according to an embodiment of the present disclosure.

FIG. 2 is a graph illustrating a relationship between a pressure and a flow rate depending on a change in the opening degree of an air control valve according to an embodiment of the present disclosure.

FIG. 3 is a graph illustrating a relationship between a power of the air compressor and a flow rate depending on a change in the opening degree of the air control valve according to an embodiment of the present disclosure.

FIG. 4 is a flowchart illustrating an inspection method of an air compressor for a fuel cell according to an embodiment of the present disclosure.

FIG. 5 is a flowchart of a process of calculating a correction coefficient required when inspecting the air compressor for the fuel cell according to an embodiment of the present disclosure.

### DETAILED DESCRIPTION

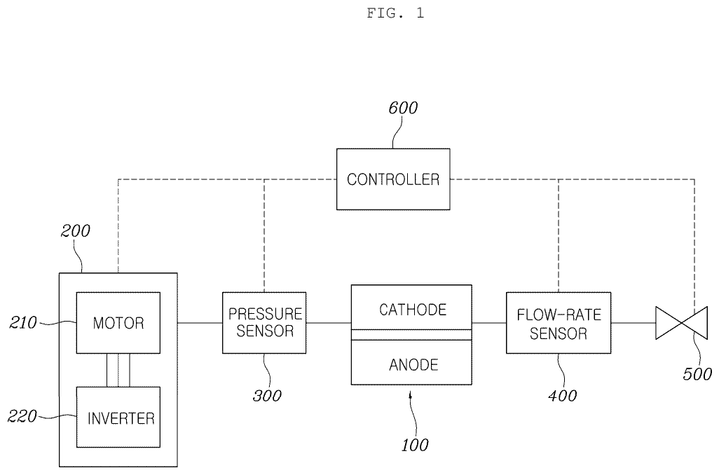

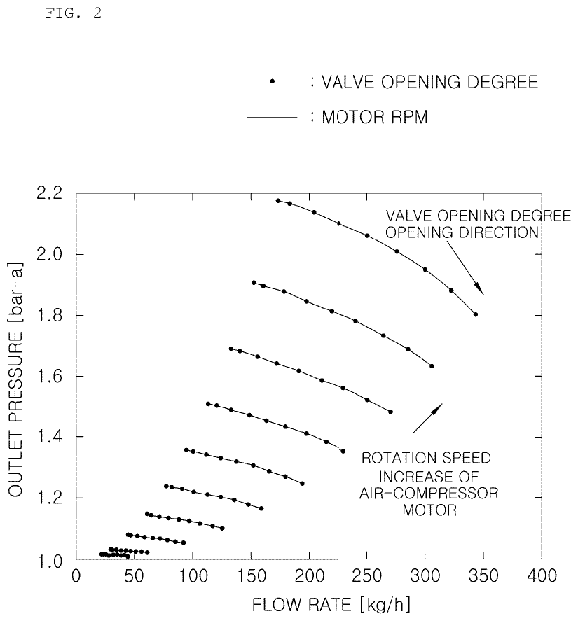

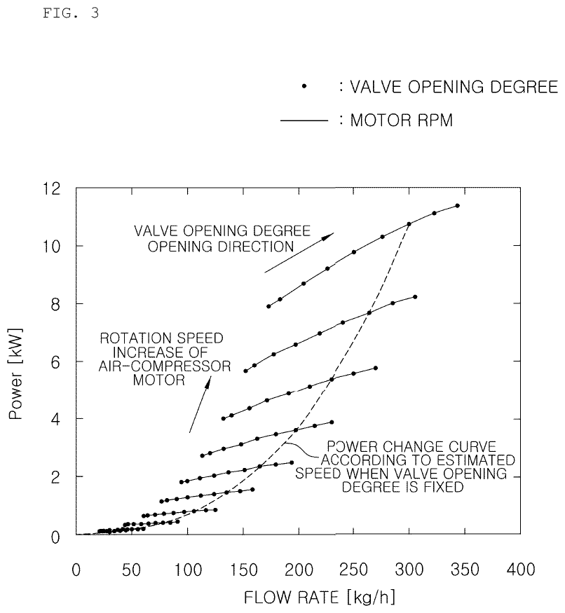

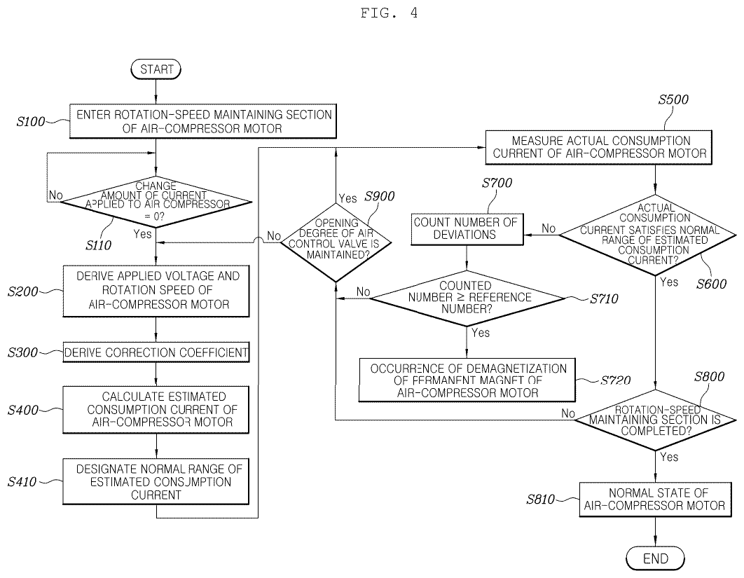

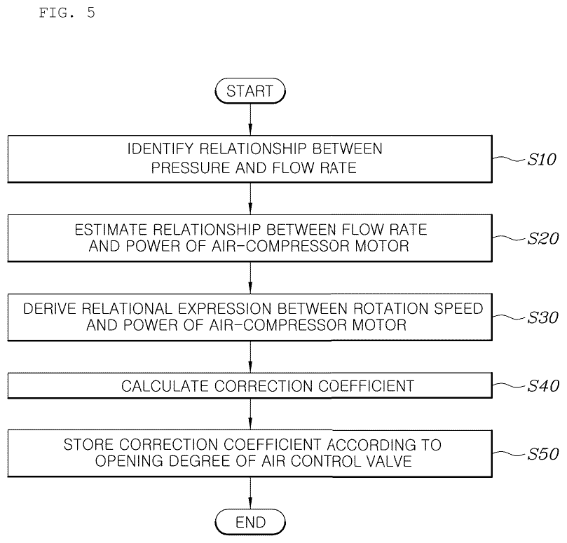

When a component, device, element, or the like of the present disclosure is described as having a purpose or performing an operation, function, or the like, the component, device, or element should be considered herein as being “configured to” meet that purpose or to perform that operation or function. FIG. 1 is a diagram illustrating the configuration of an inspection system of an air compressor for a fuel cell according to an embodiment of the present disclosure. FIG. 2 is a graph illustrating a relationship between a pressure and a flow rate depending on a change in the opening degree of an air control valve according to an embodiment of the present disclosure. FIG. 3 is a graph illustrating a relationship between a power of the air compressor and a flow rate depending on a change in the opening degree of the air control valve according to an embodiment of the present disclosure. Further, FIG. 4 is a flowchart illustrating an inspection method of an air compressor for a fuel cell according to an embodiment of the present disclosure. FIG. 5 is a flowchart of a process of calculating a correction coefficient required when inspecting the air compressor for the fuel cell according to an embodiment of the present disclosure.

FIG. 1 is a diagram illustrating the configuration of an inspection system of an air compressor for a fuel cell according to an embodiment of the present disclosure. The inspection system of the air compressor 200 for the fuel cell according to the present disclosure includes a fuel cell 100, an air compressor 200 that is provided on an inlet side of a cathode of the fuel cell 100 and is provided with a motor 210, and a controller 600. The controller 600 calculates an estimated consumption current of the air compressor 2000 through a relationship between an applied voltage and a rotation speed of the air-compressor motor. The controller 600 also compares the calculated estimated consumption current with a measured actual consumption current to determine whether a permanent magnet of the air-compressor motor is demagnetized.

The controller 600 according to an embodiment of the present disclosure may be implemented through a non-volatile memory (not shown) configured to store data about an algorithm configured to control the operation of various components of a vehicle or a software instruction for reproducing the algorithm. The controller 600 may be also implemented through a processor (not shown) configured to perform an operation, which is described below, using the data stored in the memory. In this regard, the memory and the processor may be implemented as separate chips. Alternatively, the memory and the processor may be implemented as a single integrated chip, and the processor may take the form of one or more processors.

The air compressor 200 of the present disclosure includes the motor 210 and provides compressed air, generated by driving the motor 210, to the cathode of the fuel cell 100. It should be appreciated herein that the control of the air-compressor motor 210 has the same meaning as the control of the air compressor 200. Further, in order to control the air-compressor motor 210, the inspection system of the air compressor 200 for the fuel cell may include an inverter 220. The inverter 220 controls the air-compressor motor 210 to follow a speed command. Furthermore, the inverter 220 converts an input DC voltage to a three-phase AC voltage and then provides the voltage to the air-compressor motor 210. Thus, when it is determined whether the air-compressor motor 210 is demagnetized, the three-phase voltage equation of the air-compressor motor 210 is conventionally used. By comparing a back electromotive force (EMF) constant calculated using the three-phase voltage equation with a back EMF constant in a state where demagnetization does not occur, it is determined whether the air-compressor motor 210 is demagnetized.

However, factors used in the three-phase voltage equation are problematic because a measurement error or a deviation in design may occur. For this reason, an error may occur when the back EMF constant is calculated using the three-phase voltage equation, and this error may deteriorate the accuracy of the demagnetization diagnosis of the permanent magnet of the air-compressor motor 210. In order to solve the problem, according to the present disclosure, the estimated consumption current of the air compressor 200 is calculated through the relationship between the applied voltage and the rotation speed of the air-compressor motor 210. Further, it is determined whether the air-compressor motor 210 is demagnetized by comparing the calculated estimated consumption current with the measured actual consumption current. In particular, there are various elements that may cause demagnetization in the air-compressor motor 210. However, in the present disclosure, it is determined whether the permanent magnet of the air-compressor motor 210 is demagnetized.

The controller 600 provided in the inspection system of the air compressor 200 for the fuel cell calculates the estimated consumption current of the air-compressor motor 210 through the relationship between the voltage applied to the air-compressor motor 210 and the rotation speed. At this time, the controller 600 calculates the estimated consumption current of the air-compressor motor 210 by reflecting the correction coefficient in the relationship between the applied voltage and the rotation speed of the air-compressor motor 210. Therefore, the controller 600 needs to previously calculate and store a correction coefficient that is required to calculate the estimated consumption current of the air-compressor motor 210.

The inspection system of the air compressor 200 for the fuel cell according to the present disclosure further includes an air control valve 500 provided on an outlet side of the cathode of the fuel cell 100. The inspection system further includes a pressure sensor 300 provided between the air compressor 200 and the air control valve 500 to measure the pressure of air discharged from the air compressor 200. The inspection system further includes a flow-rate sensor 400 provided between the air compressor 200 and the air control valve 500 to measure the flow rate of air discharged from the air compressor 200. The controller 600 utilizes data obtained through the air control valve 500, the pressure sensor 300, and the flow-rate sensor 400 so as to calculate the correction coefficient. In particular, the controller 600 estimates a relationship between the power and the rotation speed of the air-compressor motor 210 through the relationship between the pressure and the flow rate measured through the pressure sensor 300 and the flow-rate sensor 400 in a state where the opening degree of the air control valve 500 is fixed.

FIG. 2 is a graph illustrating the relationship between the pressure and the flow rate depending on a change in the opening degree of the air control valve according to an embodiment of the present disclosure. FIG. 3 is a graph illustrating a relationship between the power of the air compressor and the flow rate depending on a change in the opening degree of the air control valve according to an embodiment of the present disclosure. Referring to FIGS. 2 and 3, the relationship between the power and the rotation speed of the air-compressor motor 210 may be estimated through the relationship between the pressure and the flow rate. The solid lines on the graphs of FIGS. 2 and 3 mean the rotation speed of the air-compressor motor 210, and the dots on the solid lines indicate the opening degree of the air control valve 500 when the rotation speed of the air-compressor motor 210 is constant.

To be more specific, FIG. 2 is a graph showing data about the pressure and the flow rate obtained through the pressure sensor 300 and the flow-rate sensor 400 depending on the change in the opening degree of the air control valve 500 and the rotation speed of the air-compressor motor 210. As the rotation speed of the air-compressor motor 210 increases in a state where the opening degree of the air control valve 500 is constant, the pressure and the flow rate increase. Further, as the opening degree of the air control valve 500 is increased in a state where the rotation speed of the air-compressor motor 210 is constant, the flow rate is increased, but the pressure is reduced. Based on this, the relationship between the pressure and the flow rate may be estimated.

Referring to FIG. 3, a change in power of the air-compressor motor 210 depending on the flow rate may be identified. As the rotation speed of the air-compressor motor 210 increases in a state where the opening degree of the air control valve 500 is constant, the power of the air-compressor motor 210 increases. Considering this in relation to the graph of FIG. 2, it can be said that the pressure depending on the rotation speed of the air-compressor motor 210 and the power of the air-compressor motor 210 have the same characteristics when the opening degree of the air control valve 500 is constant. Further, as the opening degree of the air control valve 500 increases in the state where the rotation speed of the air-compressor motor 210 is constant, the power of the air-compressor motor 210 increases. As the opening degree of the air control valve 500 increases, it is necessary to compress a larger amount of air so that the air-compressor motor 210 rotates up to a target speed followed by the inverter 220. Thus, as the opening degree of the air control valve 500 increases, the power of the air-compressor motor 210 increases. Considering this in relation to the graph of FIG. 2, it can be said that the pressure depending on the opening degree of the air control valve 500 and the power of the air-compressor motor 210 are inversely proportional to each other when the rotation speed of the air-compressor motor 210 is constant.

Therefore, the relationship between the flow rate and the power of the air-compressor motor 210 is estimated through the pressure and the flow rate obtained via the pressure sensor 300 and the flow-rate sensor 400 and through the rotation speed of the air-compressor motor 210 obtained via the inverter 220. Further, based on this, the relationship between the rotation speed and the power of the air-compressor motor 210 may be estimated in a state where the opening degree of the air control valve 500 is fixed.

Subsequently, the controller 600 calculates the correction coefficient through the relationship between the rotation speed and the power of the air-compressor motor 210, which is estimated in a state where the opening degree of the air control valve 500 is fixed. Thereafter, the calculated correction coefficient is stored to correspond to the opening degree of the air control valve 500. In order to calculate the correction coefficient through the estimated relationship between the rotation speed and the power of the air-compressor motor 210, it is necessary to establish a relational expression between the rotation speed and the power of the air-compressor motor 210. The air-compressor motor 210 has rotational acceleration, torque, and inertial moment by rotating. Thus, the acceleration of the air-compressor motor 210 may be expressed by the torque and the inertial moment.

$$\\ \begin{matrix}\frac{dWn}{dt} = \frac{1}{J} \times ( {T}_{e} - {T}_{m} ) & [ Equation 1 ]\end{matrix}$$

Here, Wn represents the rotation speed of the air-compressor motor 210, J represents the inertial moment, Tₑ represents electric torque, and Tₘ represents mechanical load torque. Further, the mechanical load torque, i.e., Tₘ, may be expressed by a second-order polynominal function for the rotation speed of the air-compressor motor 210. When Equation 1 is arranged as an expression for the electric torque, Tₑ, Equation 2 may be obtained.

$$\\ \begin{matrix}{T}_{e} = J \frac{dWn}{dt} + {T}_{m} = J \frac{dWn}{dt} + α \cdot {Wn}^{2} + β \cdot Wn = α \cdot {Wn}^{2} & [ Equation 2 ]\end{matrix}$$

Since β is a relatively very small value in the mechanical load torque expressed by the second-order polynominal function for the rotation speed of the air-compressor motor 210, it may be omitted. Further, a section in which the rotation speed of the air-compressor motor 210 is kept constant is described. Thus,

$$\\ \frac{dWn}{dt}$$

meaning the acceleration of the air-compressor motor 210 becomes 0. Finally, in Equation 2, the electric torque may be expressed as an expression related to the rotation speed of the air-compressor motor 210. Further, the power of the air-compressor motor 210 may be expressed by the electric torque generated from the air-compressor motor 210 and the rotation speed of the motor.

P=Tₑ×Wn=α·Wn³ Equation 31

The power P of the air-compressor motor 210 may be expressed by a product of the electric torque and the rotation speed of the air-compressor motor 210. When the electric torque derived through Equation 2 is substituted, the power of the air-compressor motor 210 may be expressed by the rotation speed of the air-compressor motor 210. Here, α represents the correction coefficient that is required when the air compressor 200 for the fuel cell according to the present disclosure is inspected. Therefore, the controller 600 calculates the correction coefficient that is the value α, through the rotation speed and the power of the air-compressor motor 210 in a state where the opening degree of the air control valve 500 is fixed.

Subsequently, the controller 600 stores the calculated correction coefficient to correspond to the fixed opening degree of the air control valve 500. When the opening degree of the air control valve 500 is input, the controller 600 has a data map outputting the correction coefficient corresponding thereto and stores the calculated correction coefficient in the data map. In the present disclosure, the correction coefficient is data that is necessary to determine the demagnetization of the permanent magnet of the air-compressor motor 210. Therefore, the controller 600 needs to store the calculated correction coefficient in a state where the opening degree of the air control valve 500 is fixed. Further, it is necessary to prepare and store a data map so that the correction coefficient corresponding to the opening degree of the air control valve 500 is output so as to use a proper correction coefficient as the opening degree of the air control valve 500 changes when it is determined that the permanent magnet of the air-compressor motor 210 is demagnetized. Thereafter, the controller 600 uses the correction coefficient when calculating the estimated consumption current of the air-compressor motor 210, which is required to determine the demagnetization of the permanent magnet of the air-compressor motor 210.

On the other hand, the controller 600 calculates the estimated consumption current of the air-compressor motor 210 in a state where the air-compressor motor 210 enters a rotation-speed maintaining section. Further, it is determined whether the permanent magnet of the air-compressor motor 210 is demagnetized by comparing the calculated estimated consumption current with the measured actual consumption current. Here, the rotation-speed maintaining section of the air-compressor motor 210 means a section in which there is no change in the amount of current applied to the air-compressor motor 210. When the change amount of the applied current occurs, the accuracy of a result value acquired in calculating the estimated consumption current or measuring the actual consumption current may be lowered. Therefore, the controller 600 prevents the change amount of the current applied to the air-compressor motor 210 from occurring and thus increases the accuracy in determining whether the permanent magnet of the air-compressor motor 210 is demagnetized. If the change amount of the applied current occurs, the controller 600 delays the entry of the air-compressor motor 210 into the rotation-speed maintaining section.

Furthermore, the reason why the air compressor 200 for the fuel cell is inspected in a state where the air-compressor motor 210 enters the rotation-speed maintaining section is because the rotation-speed maintaining section is always present between the operations of the fuel cell 100. Therefore, by utilizing a section in which the air-compressor motor 2110 enters the rotation-speed maintaining section, periodic inspection is possible between the operations of the fuel cell 100. Further, the accuracy of determining the demagnetization can be enhanced by securing a sufficient constant speed maintaining time.

When there is no change amount of the current applied to the air-compressor motor 210, the controller 600 calculates the estimated consumption current through the relationship between the applied voltage and the rotation speed of the air-compressor motor 210. The controller 600 checks the opening degree of the air control valve 500 when the estimated consumption current is calculated. The controller 600 derives the correction coefficient corresponding to the checked opening degree of the air control valve 500. Further, the estimated consumption current is calculated by reflecting the derived correction coefficient in the relationship between the applied voltage and the rotation speed of the air-compressor motor 210. The controller 600 calculates the estimated consumption current of the air-compressor motor 210 using Equation 4 based on the applied voltage and the rotation speed of the air-compressor motor 210.

$$\\ \begin{matrix}{I}_{dc \_ ref} = \frac{{P}_{ref}}{{V}_{dc}} = \frac{α \cdot {Wn}^{3}}{{V}_{dc}} & [ Equation 4 ]\end{matrix}$$

In Equation 4, I_{de_ref} represents the estimated consumption current of the air-compressor motor 210, P_{ref} represents the power of the air-compressor motor 210, and V_{de} represents the applied voltage of the air-compressor motor 210. The estimated consumption current of the air-compressor motor 210 may be expressed by the relationship between the power of the air-compressor motor 210 and the applied voltage. The power P_{ref} of the air-compressor motor 210 may be expressed through Equation 3 by the rotation speed of the air-compressor motor 210. Therefore, the estimated consumption current of the air-compressor motor 210 is expressed by the relationship between the rotation speed and the applied voltage of the air-compressor motor 210.

The controller 600 checks the opening degree of the air control valve 500 when the air-compressor motor 210 enters the rotation-speed maintaining section. The controller 600 derives the correction coefficient corresponding to the opening degree of the air control valve 500 checked from the data map in which the opening degree of the air control valve 500 is checked and stored. The controller 600 checks the derived correction coefficient, the rotation speed of the air-compressor motor 210, and the applied voltage of the air-compressor motor 210 to calculate the estimated consumption current I_{dc_ref} of the air-compressor motor 210 through Equation 4.

Subsequently, the controller 600 measures current that is consumed by the air-compressor motor 210 after the air-compressor motor 210 enters the rotation-speed maintaining section, calculates the average value of current consumed for each reference time. The controller 600 also uses the calculated average value as the actual consumption current of the air compressor 200. The controller 600 needs to measure the actual consumption current of the air-compressor motor 210 so as to determine whether a problem occurs based on the estimated consumption current that is calculated when the air-compressor motor 210 enters the rotation-speed maintaining section. However, the consumption current of the air-compressor motor 210 may have an unstable value that is not constant, in the rotation-speed maintaining section of the air-compressor motor 210. Thus, the controller 600 continues to measure the current consumed by the air-compressor motor 210 while entering the rotation-speed maintaining section of the air-compressor motor 210. Based on the continuously measured consumption current, the controller 600 calculates an average value for each reference time. The average value calculated for each reference time may have a difference, and the measured actual consumption current may also vary each time. Further, by comparing the varying actual consumption current with the calculated estimated consumption current, there is an effect of increasing the accuracy in determining the demagnetization of the permanent magnet of the air-compressor motor 210, which may change over time.

On the other hand, the controller 600 designates a normal range of the calculated estimated consumption current when comparing the calculated estimated consumption current with the actual consumption current. The controller 600 also checks whether the measured actual consumption current falls within the normal range of the estimated consumption current. When the actual consumption current deviates from the normal range of the estimated consumption current, the number of deviations is counted. There is a problem in that a measurement error may occur in measuring the data required for calculating the estimated consumption current. When comparing the estimated consumption current with the actual consumption current, it is necessary to designate the normal range of the estimated consumption current so as to solve the determination error of the controller 600 due to the occurrence of the measurement error. The normal range of the estimated consumption current may be composed of minimum estimated consumption current and maximum estimated consumption current reflecting the measurement error that may occur. Thereafter, the controller 600 measures the actual consumption current to check whether the actual consumption current falls within the normal range of the estimated consumption current.

The estimated consumption current means current in a normal state in which demagnetization does not occur in the permanent magnet of the air-compressor motor 210. Thus, the controller 600 compares the measured actual consumption current and the estimated consumption current that is theoretically estimated in the normal state so as to determine whether the permanent magnet of the air-compressor motor 210 is demagnetized. When the measured actual consumption current is different from the estimated consumption current due to the driving of the actual air-compressor motor 210, it means that there is an abnormality in the air-compressor motor 210. Therefore, the controller 600 needs to determine whether the permanent magnet of the air-compressor motor 210 is demagnetized by comparing the measured actual consumption current and the theoretically calculated estimated consumption current. Particularly, the controller 600 checks whether the measured actual consumption current falls within the normal range of the calculated estimated consumption current to determine whether the permanent magnet of the air-compressor motor 210 is demagnetized. Thus, when the measured actual consumption current deviates from the normal range of the estimated consumption current, the controller 600 needs to count the number of deviations.

When the actual consumption current deviates from the normal range of the estimated consumption current, the controller 600 compares the counted number and a pre-stored reference number of determining the demagnetization of the permanent magnet of the air-compressor motor 210. Further, when the counted number is equal to or more than the reference number, the controller 600 determines that the demagnetization occurs in the permanent magnet of the air-compressor motor 210. The controller 600 continues to measure the actual consumed current while the air-compressor motor 210 enters the rotation-speed maintaining section. Further, the controller 600 counts the number of times the measured actual consumption current deviates from the normal range of the estimated consumption current. The controller 600 may store the reference number of determining the demagnetization of the permanent magnet of the air-compressor motor 210. Thus, the controller 600 may easily determine whether the permanent magnet of the air-compressor motor 210 is demagnetized by comparing the counted number and the stored reference number.

However, when the counted number is less than the reference number, the controller 600 checks whether the opening degree of the air control valve 500 is maintained at an opening degree when the air-compressor motor 210 enters the rotation-speed maintaining section. Further, when the opening degree of the air control valve 500 is maintained, the controller 600 measures the actual consumption current of the air-compressor motor 210 again. When the counted number is less than the reference number, the controller 600 may not precisely determine whether the permanent magnet of the air-compressor motor 210 is demagnetized yet, so it is necessary to compare the actual consumption current and the estimated consumption current again. However, when measuring the actual consumption current, it is necessary to check whether the opening degree of the air control valve 500 is maintained at the opening degree when entering the rotation-speed maintaining section of the air-compressor motor 210. When the opening degree of the air control valve 500 is not maintained, the actual consumption current is measured differently, which causes an error in the comparison between the actual consumption current and the estimated consumption current. Therefore, the controller 600 needs to measure the actual consumption current by checking whether the opening degree of the air control valve 500 is maintained. When the opening degree of the air control valve 500 is not maintained, the controller 600 checks the opening degree of the air control valve 500 again, derives the correction coefficient corresponding thereto, and calculates the estimated consumption current again. Thus, it is possible to check an error that may occur due to internal or external factors by comparing the actual consumption current and the estimated consumption current. Further, by responding to prevent the checked error from occurring, the accuracy of determining the demagnetization of the permanent magnet of the air-compressor motor 210 may be increased.

On the other hand, if the measured actual consumption current is within the normal range of the estimated consumption current, the controller 600 determines whether the rotation-speed maintaining section of the air-compressor motor 210 is completed. The controller 600 also determines the completion of the rotation-speed maintaining section as the normal state where the demagnetization of the permanent magnet of the air-compressor motor 210 does not occur. If the measured actual consumption current falls within the normal range of the estimated consumption current, the controller 600 determines whether the rotation-speed maintaining section of the air-compressor motor 210 is completed. The actual consumption current may be changed in the rotation-speed maintaining section of the air-compressor motor 210, so the actual consumption current may fall within or deviate from the allowable range of the estimated consumption current. In other words, when the rotation-speed maintaining section of the air-compressor motor 210 is not completed, it may not be accurate to determine the demagnetization of the permanent magnet of the air-compressor motor 210 even if the actual consumption current falls within the allowable range of the estimated consumption current. Therefore, when the actual consumption current falls within the normal range of the estimated consumption current and the rotation-speed maintaining section is completed, the controller 600 determines that this is the normal state where the demagnetization of the permanent magnet of the air-compressor motor 210 does not occur.

However, when the rotation-speed maintaining section of the air-compressor motor 210 is not completed, the controller 600 checks whether the opening degree of the air control valve 500 is maintained at the opening degree when entering the rotation-speed maintaining section of the air-compressor motor 210. If the opening degree of the air control valve 500 is maintained, the controller 600 measures the actual consumption current of the air-compressor motor 210 again. When the opening degree of the air control valve 500 is not maintained, the actual consumption current is measured differently, which causes an error when comparing the actual consumption current and the estimated consumption current. Therefore, the controller 600 needs to check whether the opening degree of the air control valve 500 is maintained, and then measure the actual consumption current. Further, the controller 600 measures the actual consumption current in this section until the rotation-speed maintaining section of the air-compressor motor 210 is completed even if the measured actual consumption current falls within the normal range of the estimated consumption current. Thus, it is possible to precisely determine the demagnetization of the permanent magnet of the air-compressor motor 210, which occurs in the rotation-speed maintaining section of the air-compressor motor 210.

FIG. 4 is a flowchart illustrating an inspection method of an air compressor for a fuel cell according to an embodiment of the present disclosure. FIG. 5 is a flowchart of a process of calculating a correction coefficient required when inspecting the air compressor for the fuel cell according to an embodiment of the present disclosure. The inspection method of the air compressor 200 for the fuel cell according to the present disclosure includes a step S200 of deriving the applied voltage and the rotation speed of the air-compressor motor 210 in the controller 600. The inspection method also includes a step S400 of calculating estimated consumption current of the air-compressor motor 210 through a relationship between the applied voltage and the rotation speed of the air-compressor motor 210 in the controller 600. The inspection method also includes steps the S600, S710, and 3820 of determining whether a permanent magnet of the air-compressor motor 210 is demagnetized by comparing estimated consumption current calculated in the controller 600 with the measured actual consumption current.

As shown in FIG. 4, in order to determine whether the permanent magnet of the air-compressor motor 210 is demagnetized, the air-compressor motor 210 enters the rotation-speed maintaining section (S100). When entering the rotation-speed maintaining section, the controller 600 checks the change amount of current applied to the air-compressor motor 210 (S110). When there is the change amount of the current applied to the air-compressor motor 210 (No in S110), the controller continues to check the applied current until there is no change amount. When there is no change amount of current applied to the air-compressor motor 210 (Yes in S110), the controller 600 measures the applied voltage and the rotation speed of the air-compressor motor 210 (S200). Further, when the air-compressor motor 210 enters the rotation-speed maintaining section, the opening degree of the air control valve 500 is checked, and the correction coefficient corresponding thereto is derived (S300). At the step of calculating the estimated consumption current of the air-compressor motor 210, the estimated consumption current of the air-compressor motor 210 is calculated by reflecting the correction coefficient in the relationship between the applied voltage and the rotation speed of the air-compressor motor 210 in the controller 600 (S400).

In this regard, the correction coefficient is derived according to the opening degree of the air control valve 500. The correction coefficient is calculated through the relationship between the power and the rotation speed of the air-compressor motor 210 to be stored together with the opening degree of the air control valve 500. The process of calculating the correction coefficient may be seen with reference to FIG. 5.

As shown in FIG. 5, the controller 600 identifies the relationship between the pressure and the flow rate, which are measured through the pressure sensor 300 and the flow-rate sensor 400 (S10). Further, the relationship between the flow rate and the power of the air-compressor motor 210 is estimated through the relationship between the pressure and the flow rate, which is identified in the controller 600 (S20). By estimating the relationship between the flow rate and the power of the air-compressor motor 210, the controller 600 may estimate the relationship between the power and the rotation speed of the air-compressor motor 210. Particularly, in a state where the opening degree of the air control valve 500 is fixed, the relationship between the power and the rotation speed of the air-compressor motor 210 is estimated. Thereafter, a relational expression is derived based on the relationship between the power and the rotation speed of the air-compressor motor 210, which is estimated in the controller 600 (S30). If the power and the rotation speed of the air-compressor motor 210 are measured in the controller 600, the correction coefficient is calculated through the measured data (S40). The controller 600 stores the calculated correction coefficient to correspond to the fixed opening degree of the air control valve 500 (S50). At this time, the controller 600 is provided with the data map to which the correction coefficient is output, when the opening degree of the air control valve 500 is input. If the calculation and storage of the correction coefficient are completed, the controller 600 determines the demagnetization of the permanent magnet of the air-compressor motor 210.

As shown in FIG. 4, when the estimated consumption current of the air-compressor motor 210 is calculated (S400), the controller 600 designates the normal range of the calculated estimated consumption current (S410). Further, the controller 600 checks whether the measured actual consumption current falls with the normal range of the estimated consumption current and determines whether the permanent magnet of the air-compressor motor 210 is demagnetized. In order to prevent the determination error due to an error that may occur in calculating the estimated consumption current, the controller 600 designates the normal range of the estimated consumption current using an expected error value that may occur (S410). Further, the controller 600 measures an actual current that is consumed by the air-compressor motor 210 (S500). It is determined whether the permanent magnet of the air-compressor motor 210 is demagnetized using the measured actual consumption current and the calculated estimated consumption current.

Specifically, it is determined whether the measured actual consumption current falls within the normal range of the calculated estimated consumption current (S600). When the measured actual consumption current falls within the normal range of the estimated consumption current (Yes in S600), the controller 600 checks whether the rotation-speed maintaining section of the air-compressor motor 210 is completed (S800). When the rotation-speed maintaining section of the air-compressor motor 210 is completed (Yes in S800), the controller 600 determines it as the normal state where the permanent magnet of the air-compressor motor 210 is not demagnetized (S810). However, when the rotation-speed maintaining section of the air-compressor motor 210 is not completed (No in S800), the controller 600 checks whether the initially checked opening degree of the air control valve 500 is maintained (S900). When the opening degree of the air control valve 500 is maintained (Yes in S900), the actual consumption current of the air-compressor motor 210 is measured again (S500), so it is necessary to determine whether the permanent magnet of the air-compressor motor 210 is demagnetized.

When the measured actual consumption current deviates from the normal range of the estimated consumption current (No in S600), the controller 600 counts the number of deviations (3700). The controller 600 accumulates the counted number and compares the counted number with the reference number of determining the demagnetization of the permanent magnet of the air-compressor motor 210 (3710). When the counted number is equal to or more than the reference number (Yes in S710), the controller 600 determines that the permanent magnet of the air-compressor motor 210 is demagnetized (S720). In contrast, when the counted number is less than the reference number (No in S710), the controller 600 checks whether the initially checked opening degree of the air control valve 500 is maintained (3900). If the opening degree of the air control valve 500 is maintained (Yes in S900), it is necessary to determine whether the permanent magnet of the air-compressor motor 210 is demagnetized, by measuring the actual consumption current of the air-compressor motor 210 again (S500).

However, when the opening degree of the air control valve 500 is not maintained (No in S900), the controller 600 checks the opening degree of the air control valve 500 again and derives the applied voltage and rotation speed of the air-compressor motor 210 corresponding thereto again (S200). Further, the controller 600 derives the correction coefficient corresponding to the air control valve 500, which is checked again (S300). Thus, the estimated consumption current of the air-compressor motor 210 is calculated again (S400), and subsequent steps are repeatedly performed in the controller 600.

As described above, the present disclosure provides a system and method of inspecting an air compressor for a fuel cell. In the system and method, the estimated consumption current of an air-compressor motor is calculated through a relationship between the applied voltage and rotation speed of the air-compressor motor, so it is determined that a permanent magnet of the air-compressor motor is demagnetized. Thus, the occurrence of determination errors due to errors of measurement elements and design deviations is reduced and accuracy is enhanced.

Furthermore, when it is determined that a permanent magnet of an air-compressor motor is demagnetized, both internal and external elements of an air compressor are inspected. Thus, the accuracy of determining that the air-compressor motor is demagnetized is enhanced.

Although the present disclosure is described with reference to specific embodiments shown in the drawings, it is apparent to those having ordinary skill in the art that the present disclosure may be changed and modified in various ways without departing from the scope of the present disclosure, which is described in the following claims.

What is claimed is:

1. An inspection system of an air compressor for a fuel cell, the inspection system comprising:
the fuel cell;
an air compressor provided on an inlet side of a cathode of the fuel cell and provided with a motor; and
a controller configured to calculate an estimated consumption current of the motor of the air-compressor through a relationship between an applied voltage and a rotation speed of the motor of the air-compressor and configured to compare the calculated estimated consumption current with a measured actual consumption current to determine whether a permanent magnet of the motor of the air-compressor is demagnetized.

2. The inspection system of claim 1, further comprising:
an air control valve provided on an outlet side of the cathode of the fuel cell;
a pressure sensor provided between the air compressor and the air control valve to measure pressure of air discharged from the air compressor; and
a flow-rate sensor provided between the air compressor and the air control valve to measure a flow rate of air discharged from the air compressor,
wherein the controller estimates a relationship between a power and a rotation speed of the motor of the air-compressor through a relationship between the pressure and the flow rate measured through the pressure sensor and the flow-rate sensor in a state where an opening degree of the air control valve is fixed.

3. The inspection system of claim 2, wherein the controller calculates a correction coefficient through the relationship between the power and the rotation speed of the motor of the air-compressor, wherein the relationship between the power and the rotation speed of the motor of the air-compressor is estimated in a state where the opening degree of the air control valve is fixed, and wherein the controller stores the calculated correction coefficient to correspond to the opening degree of the air control valve.

4. The inspection system of claim 3, wherein the controller comprises a data map outputting the correction coefficient corresponding to an input opening degree of the air control valve and stores the calculated correction coefficient in the data map.

5. The inspection system of claim 3, wherein the controller checks the opening degree of the air control valve when the estimated consumption current is calculated, derives the correction coefficient corresponding to the checked opening degree of the air control valve, and calculates the estimated consumption current by reflecting the derived correction coefficient in the relationship between the applied voltage and the rotation speed of the motor of the air-compressor.

6. The inspection system of claim 1, wherein the controller calculates the estimated consumption current of the motor of the air-compressor in a state where the motor of the air-compressor enters a rotation-speed maintaining section and determines whether the permanent magnet of the motor of the air-compressor is demagnetized by comparing the calculated estimated consumption current with the measured actual consumption current.

7. The inspection system of claim 6, wherein the rotation-speed maintaining section of the motor of the air-compressor is a section in which there is no change in an amount of current applied to the motor of the air-compressor.

8. The inspection system of claim 6, wherein the controller measures current that is consumed by the motor of the air-compressor after the motor of the air-compressor enters the rotation-speed maintaining section, calculates an average value of current consumed for each reference time, and uses the calculated average value as the actual consumption current of the motor of the air-compressor.

9. The inspection system of claim 6, wherein the controller designates a normal range of the calculated estimated consumption current when comparing the calculated estimated consumption current with the actual consumption current, checks whether the measured actual consumption current falls within the normal range of the estimated consumption current, and counts a number of deviations when the actual consumption current deviates from the normal range of the estimated consumption current.

10. The inspection system of claim 9, wherein, if the measured actual consumption current is within the normal range of the estimated consumption current, the controller determines whether the rotation-speed maintaining section of the motor of the air-compressor is completed, and determines completion of the rotation-speed maintaining section as a normal state where the demagnetization of the permanent magnet of the motor of the air-compressor does not occur.

11. The inspection system of claim 10, wherein the controller checks whether the opening degree of the air control valve is maintained at the opening degree when entering the rotation-speed maintaining section of the motor of the air-compressor, if the rotation-speed maintaining section of the motor of the air-compressor is not completed, and wherein the controller measures the actual consumption current of the motor of the air-compressor again when the opening degree of the air control valve is maintained.

12. The inspection system of claim 9, wherein the controller compares the counted number with a pre-stored reference number of determining the demagnetization of the permanent magnet of the motor of the air-compressor when the actual consumption current deviates from the normal range of the estimated consumption current, and wherein the controller determines that the demagnetization occurs in the permanent magnet of the motor of the air-compressor when the counted number is equal to or more than the reference number.

13. The inspection system of claim 12, wherein, when the counted number is less than the reference number, the controller checks whether the opening degree of the air control valve is maintained at an opening degree when the motor of the air-compressor enters the rotation-speed maintaining section, and wherein, when the opening degree of the air control valve is maintained, the controller measures the actual consumption current of the motor of the air-compressor again.

14. An inspection method of an air compressor for a fuel cell, the inspection method comprising:
deriving, by a controller, an applied voltage and a rotation speed of an air-compressor motor;
calculating, by the controller, estimated consumption current of the air-compressor motor through a relationship between the applied voltage and the rotation speed of the air-compressor motor; and
determining whether a permanent magnet of the air-compressor motor is demagnetized by comparing the estimated consumption current calculated by the controller with measured actual consumption current.

15. The inspection method of claim 14, wherein, in the calculating of the estimated consumption current of the air-compressor motor, the estimated consumption current of the air-compressor motor is calculated by reflecting a correction coefficient in the relationship between the applied voltage and the rotation speed of the air-compressor motor in the controller, the correction coefficient is derived according to the opening degree of the air control valve, and the correction coefficient is calculated through a relationship between power and the rotation speed of the air-compressor motor to be stored together with the opening degree of the air control valve.

16. The inspection method of claim 14, wherein, in the determining whether the permanent magnet of the air-compressor motor is demagnetized, the controller designates a normal range of the calculated estimated consumption current, checks whether the measured actual consumption current falls with the normal range of the estimated consumption current, and determines whether the permanent magnet of the air-compressor motor is demagnetized.
